(19) United States
(12) Patent Application Publication
(10) Pub. No.: US 2023/0026485 A1
(43) Pub. Date: Jan. 26, 2023

(54) Diamond Structures For Tooling

(71) Applicant: AKHAN Semiconductor, Inc., Gurnee, IL (US)

(72) Inventors: Adam Khan, San Francisco, CA (US); Kiran Kumar Kovi, Buffalo Grove, IL (US)

(21) Appl. No.: 17/869,491

(22) Filed: Jul. 20, 2022

Related U.S. Application Data
(60) Provisional application No. 63/223,752, filed on Jul. 20, 2021.

(51) Int. Cl. B23B 27/14; C23C 16/27

(52) U.S. Cl. CPC B23B 27/14; C23C 16/274; B23B 2228/105; B23B 2226/31

(57) ABSTRACT

A tool such as a wafer handler or wafer chuck can include a surface having at least one protrusion. A diamond coating is formed from diamond grains sized so that 90% of the grains are between 200 and 300 nanometers, with the diamond coating being deposited on the surface at a temperature below 500 degrees Celsius over the at least one protrusion. Dopants can be used to provide electrical conductivity needed for electrostatic wafer chuck.

### RELATED APPLICATION

The present disclosure is part of a non-provisional patent application claiming the priority benefit of U.S. Patent Application No. 63/223,752, filed on Jul. 20, 2021, which is incorporated by reference in its entirety.

### TECHNICAL FIELD

The present disclosure relates generally to the field of materials and coatings for improving tooling properties. More specifically, diamond bump structures and methods for manufacture are disclosed for wafer support tooling.

### BACKGROUND

There is a demand for tooling having coatings or structures that improve performance. For example, tools may have coatings that improve hardness, reduce wear, reduce chemical reactivity, or increase or decrease frictional properties.

As an example, semiconductor wafers can be handled with vacuum or electrostatic chuck tools that that can be coated with materials that reduce wear. Coated chuck tools need to support and move wafers through many steps of wafer lithography and processing with nanometer scale precision. Unfortunately, wafers can twist or droop. When lowered onto a wafer chuck, the wafer can be prevented from flattening or moving into the correct position by friction between the wafer and chuck tool. To reduce such frictional effects, contact area between the wafer and the chuck tool can reduced by providing raised regions of near uniform height, typically regularly spaced, on the chuck tool. These raised regions are known as burls and can help in reducing the friction so that the wafer can move across the burls as its flattens and settles on the chuck tool. Often, non-uniform or malformed burls can abrade or damage the wafer.

Materials, structures and procedures that reduce or eliminate issues with friction and abrasion for tooling are needed.

### BRIEF DESCRIPTION OF THE DRAWINGS

Non-limiting and non-exhaustive embodiments of the present disclosure are described with reference to the following figures, wherein like reference numerals refer to like parts throughout the various figures unless otherwise specified.

FIGS. 1A and 1B are cross-sectional and top views of a conformal diamond coated tool surface with protrusions;

FIG. 1C is a photograph of a cross section of a conformal diamond coated protrusion;

FIG. 1D illustrates selected diamond grain sizes; and

FIG. 2 illustrates one embodiment of a process for manufacture of conformal diamond coated tool surface.

### DETAILED DESCRIPTION

In some embodiments such as described with respect to the disclosed Figures and specification a tool such as a wafer handler or wafer chuck can include a surface having at least one protrusion. A diamond coating is formed from diamond grains sized so that 90% of the grains are between 200 and 300 nanometers, with the diamond coating being deposited at a temperature respectively below 600, 500, or 450 degrees Celsius over the at least one protrusion. Dopants can be used to provide electrical conductivity needed for an electrostatic wafer chuck.

In some embodiments, the at least one protrusion is a burl or plurality of burls that at least partially extend over the tool surface and can support a wafer or other object.

In some embodiments, the diamond coating is formed to have equally sized grains of less than 1 micron. The diamond coating can be formed to continuously or partially cover the tool or burl protrusions.

In some embodiments the diamond coating thickness is between 200 nanometers to 100 microns. The diamond coating can be uniformly thick over selected regions of the tool or can be conformal over regions of the tool.

In one embodiment a method for diamond coating a tool includes the steps of providing a tool a surface having at least one protrusion and forming a diamond coating over the at least one protrusion. The diamond coating can be formed from diamond grains sized so that 90% of the grains are sized between 200 and 300 nanometers. The diamond coating can be deposited at a temperature below 500 degrees Celsius over the at least one protrusion.

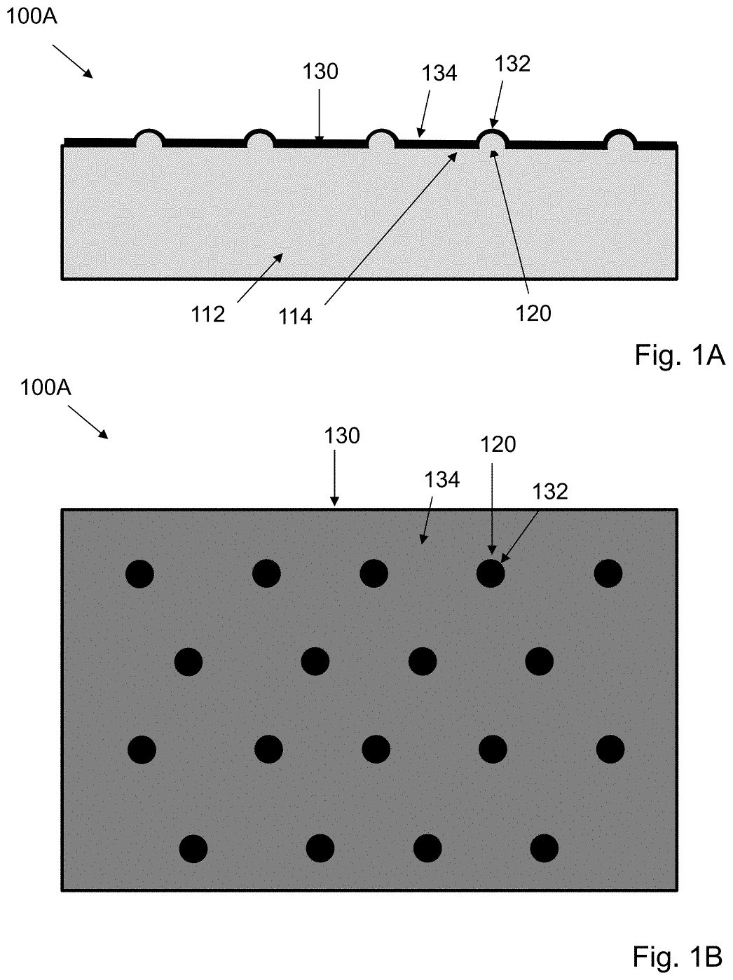

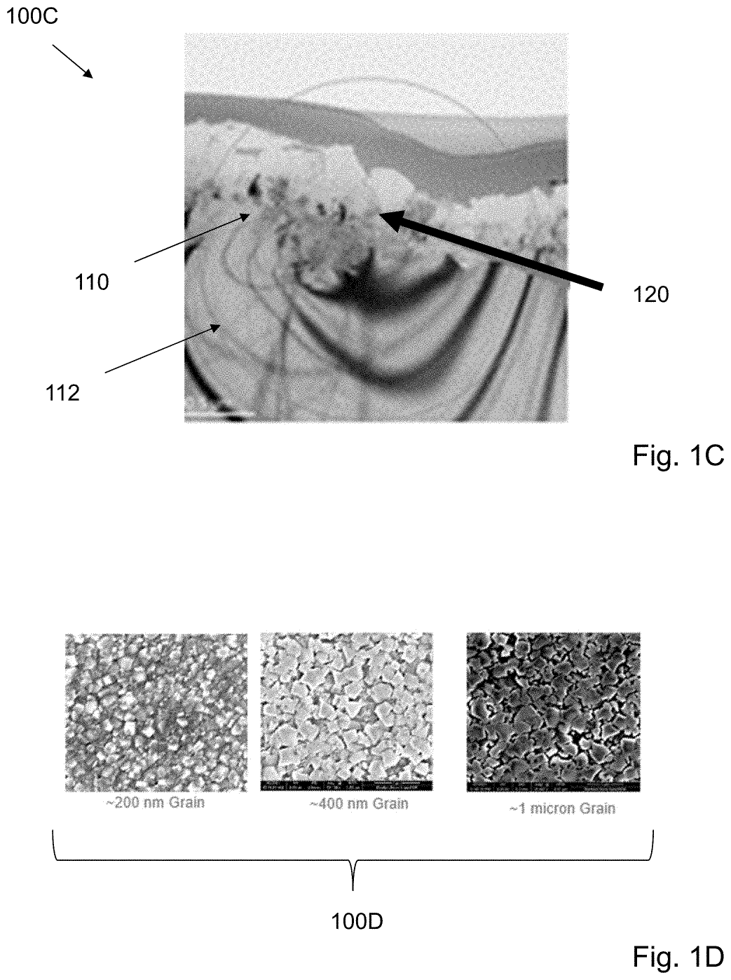

FIGS. 1A and 1B are cross-sectional (FIG. 1A) and top (FIG. 1B) views of a portion of tool 100A. The tool 100A includes a substrate 112 having a surface 114. Also present are protrusions 120 that extend away from the substrate 112. These protrusions 120 can be coated with a diamond film 130 that extends over the protrusions 120 (e.g. diamond film portion 132) and other portions of the tool surface 114 (e.g. diamond film portion 134) to provide friction reducing, protective, thermal transfer, or other needed properties. In some embodiments, the diamond film 130 conformally coats protrusions, with thickness of the coating remaining constant, or with a diamond coating thickness that varies by respectively less than 500, 300, or 100 nanometers as it extends over each of the protrusions 120. The tool 100A can be coated entirely with diamond film, coated on one or more sides, or coated in selected regions.

Tools can include but are not limited to precision carriers, graspers, lifters, or other handling tools. Tools can also include needles, pins, injectors, nano or micropipes, fluid handling channels or manifolds. Additionally, tools can be used for drilling, cutting, grinding, polishing, or insertion.

In some embodiments a tool can be a semiconductor wafer handling tool such as wafer chuck, wafer holder, wafer stage, wafer tables, wafer substrate, die scanner, wafer table for chemical mechanical polishing (CMP), or wafer transporter. For electrostatic wafer chucks or other electrically active tooling, p- or n-doping of the diamond film can be provided. In other embodiments, tools requiring or using nanoscale projections to influence mechanical, electrical, or chemical properties of the tool can be coated with diamond material. In still other embodiments, tools can be sensors or other systems that can use nanoscale projections to provide multiple point contact with other materials or the environment. For example, diamond coated sensors can be incorporated into a wafer chuck.

In some embodiments, the substrate material of the tool 100A can include Si, SiC, SiSiC, amorphous silicon, diamond-like carbon, metal-doped oxides glass materials; polymeric materials; ceramics including quartz, sapphire, and the like; metals and metal alloys; and mixtures and combinations thereof.

In some embodiments, the protrusions can include burls, mesas, bumps, pins, islands, surface structures, nano-projections, and the like. In accordance with an embodiment, protrusions on a wafer chuck may have a size, spacing, and composition that allows the maintaining of a substantially uniform pressure across the surface of wafer, and of a substantially uniform distribution of the force between the protrusions and the substrate.

In one embodiment, protrusions for wafer handling can include burls formed on a wafer tool by selective growth. Alternatively, burls can be formed by applying photoresist, patterning the photoresist, and dissolving unprotected regions. In still other embodiment, laser sintering or other additive manufacturing techniques can be used to form tool burls. Burls can be formed from substrate material, from thin films layered on the substrate, from low CTE glass-ceramic such as cordierite, from silicon carbide (SiC), from SiSiC, from aluminum nitride, or can contain SiC in the form of a composite material such as reaction-bonded SiC.

In some embodiments, there can be many hundreds or thousands of burls distributed across a wafer tools, with each burl having a diameter of at least 200 mm, 300 mm or 450 mm. Tips of the burls typically have a small area, e.g. less than 1 square millimeter. The burls can have a width (e.g., diameter) less than or equal to 0.5 mm. In an embodiment the burls have a width (e.g., diameter) in the range of from about 200 μm to about 500 μm. The spacing between burls can be between about 1.5 mm to about 3 mm.

Burls can be arranged to form a pattern and/or may have a periodic arrangement. The burl arrangement can have a regular triangular, hexagonal, square, or radial symmetry that can vary as to provide needed distribution of force from the wafer tool to the wafer. Alternatively, burls can be laid out semi-randomly, randomly, or in partially symmetric layouts. The burls can have the same shape and dimensions throughout their height but are commonly dome shaped, cone shaped, hemispherical, pyramidal, needle-like or tapered. Typically, burls project from the wafer tool in the range of from about 1 μm to about 5 mm, and often project from about 5 μm to about 250 μm. For best wafer handling results, the burls can be formed to have consistent dimensions. Variation between heights of different burls is minimized for best wafer handling results.

In some embodiments, burls or other protrusions coated with diamond film 120 can include coatings of various diamond, diamond-like, or diamond containing materials and structures. For the purposes of this disclosure, diamond refers to a crystalline structure of carbon atoms bonded to other carbon atoms in a lattice of tetrahedral coordination known as sp³ bonding. Each carbon atom can be surrounded by and bonded to four other carbon atoms, each located on the tip of a regular tetrahedron. In some embodiments the tetrahedral bonding configuration of carbon atoms can be irregular or distorted, otherwise deviate from the standard tetrahedron configuration of diamond as described above. Such distortion generally results in lengthening of some bonds and shortening of others, as well as the variation of the bond angles between the bonds. Additionally, the distortion of the tetrahedron alters the characteristics and properties of the carbon to effectively lie between the characteristics of carbon bonded in sp³ configuration (i.e. diamond) and carbon bonded in sp² configuration (i.e. graphite). One example of material having carbon atoms bonded in distorted tetrahedral bonding is amorphous diamond. In one embodiment, the amount of carbon in the amorphous diamond can be at least about 90%, with at least about 20% of such carbon being bonded in distorted tetrahedral coordination. Amorphous diamond can have a higher atomic density than that of diamond. In other diamond film embodiments, diamond-like carbon can be formed as a carbonaceous material having carbon atoms as the majority element, with a substantial amount of such carbon atoms bonded in distorted tetrahedral coordination. Diamond films can include a variety of other elements as impurities or as dopants, including without limitation, hydrogen, sulfur, phosphorous, boron, nitrogen, silicon, or tungsten. This can be useful, for example, in modifying electrical or chemical diamond film properties to support tool requirements.

Diamond deposition can be by any process such as, but not limited to, chemical vapor deposition (CVD) and physical vapor deposition (PVD). A wide variety of embodiments of vapor deposition method can be used. Examples of vapor deposition methods include hot filament CVD, rf-CVD, laser CVD (LCVD), laser ablation, conformal diamond coating processes, metal-organic CVD (MOCVD), sputtering, thermal evaporation PVD, ionized metal PVD (IMPVD), electron beam PVD (EBPVD), reactive PVD, cathodic arc, and the like.

In some embodiments, a thin diamond film can be deposited at relatively low temperatures of less than 600, 500, or 450 degrees Celsius using an activation medium like plasma, argon gas and a carbon source, such as methane. In other embodiments, deposition can be at temperatures between 375 and 425 degrees Celsius. Advantageously, as compared to conventional 700-800 degree Celsius temperatures for diamond film growth, such low temperatures greatly reduce thermal warping of tooling, including wafer handling tools. Warping is reduced for partially coated tools, tools that are diamond coated on one side, tools coated on both sides, or tools that are entirely coated with a diamond film.

In some embodiments, deposition gas is ignited and forms small diamonds that grow on a wafer, producing a continuous, thin, and conformal layer. The type and structure of diamond deposited is dependent on the seed method used. Large grain seed can result in microcrystalline diamond with increased hardness. Small grain sizes in nanocrystalline diamond can provide lower surface roughness.

Properties of diamond film can be measured and characterized using Raman spectroscopy. Cubic diamond has a single Raman-active first order phonon mode at the center of the Brillouin zone. The presence of sharp Raman lines allows cubic diamond to be recognized against a background of graphitic or other carbon crystal types. Small shifts in the band wavenumber can indicate diamond composition and properties. In some embodiments, the full width half maximum (FWHM) obtained from Raman characterization for the diamond films formed as indicated in this disclosure can be between 5-10.

In some embodiments the diamond film can be conformally deposited over as a continuous layer over the surface 114 of the tool 100A. Alternatively, with the use of masking, etching, or suitable growth enhancing or growth reducing techniques, only selected area(s) can be provided with a diamond film. In some embodiments, diamond film thickness can be constant across the surface, while in other embodiments thickness can vary according to position.

In some embodiments, diamond film thickness can be constant across the surface, while in other embodiments thickness can vary according to position. Diamond coating thickness can be between 200 nm to 100 microns. In some embodiments, diamond coating thickness can be between 200 nm to 10 microns. In some embodiments, diamond coating thickness can be between 200 nm to 1 micron. In some embodiments, diamond grain size can be between 200 and 300 nanometers. In some embodiments, 90% of the diamond grains are between 200 and 300 nanometers. In other embodiments, 95% of the diamond grains are between 200 and 300 nanometers, and in still other embodiments, 99% of the diamond grains are between 200 and 300 nanometers.

FIG. 1C is a photograph of a cross section of a conformal diamond coated protrusion.

FIG. 1D illustrates selected diamond grain sizes. As illustrated, 200 nm, 400 nm, and 1 micron grain sizes are shown. As is apparent, grain sizes are nearly uniform, with at least 90% of the diamond grains being sized between 200 and 300 nanometers

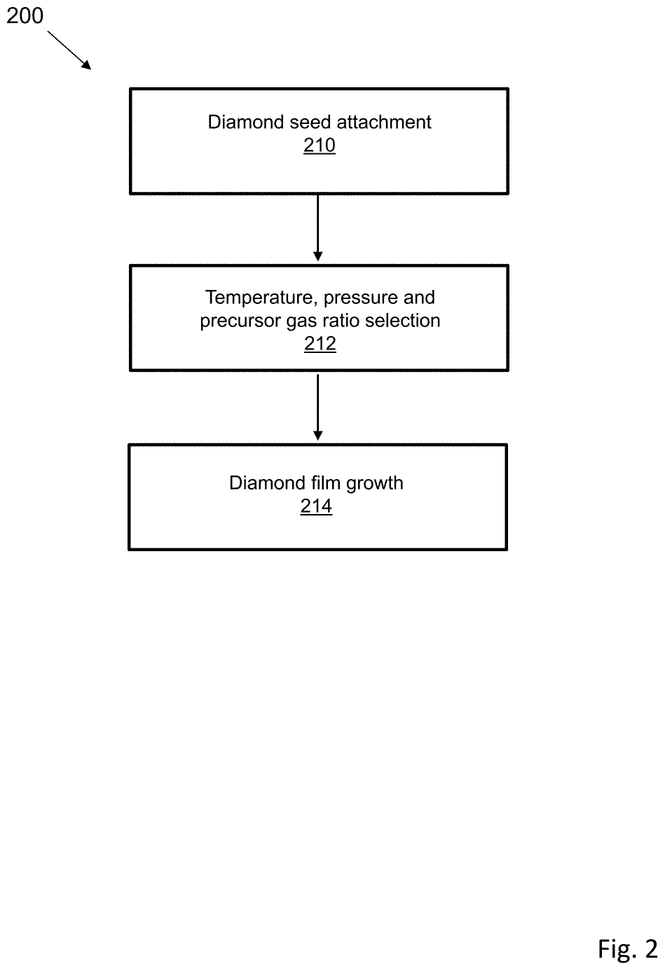

FIG. 2 illustrates one embodiment of a process 200 for manufacture of a diamond coated tool surface. In a first process step 210 diamond seeds are attached to a tool surface. Suitable diamond seeds with sizes between 5 nm to 25 um can be attached to the substrate by sonication. This increases nucleation density, improves uniformity, and speeds growth rate. Seeding techniques can varied as necessary to provide desired diamond film thickness thicknesses and grain size.

In a second process step 212 temperature, pressure and precursor gas ratios can be selected to achieve the desired film thicknesses and grain size. In some embodiments the precursor gases can include methane, hydrogen and argon. Other minor proportions of gases such as boron, nitrogen, or phosphorus can be used if desired. Low temperature growth at pressures of 10-100 Torr can be selected.

In a third process step 214 diamond films are grown in either a hot filament CVD reactor or a microwave plasma reactor. In case of HFCVD rector, tungsten or tantalum filaments are used, and they can be carburized prior to nucleation and growth. In some embodiments, grown diamond films can have grain sizes categorized as microcrystalline (typically 500 nm or greater), nanocrystalline (typically 10-500 nm) or ultra-nanocrystalline (typically 2 to 10 nm).

Example 1—In other embodiments, nanocrystalline diamond can be deposited on SiSiC substrates that are between 2 and 12 inches in diameter. The SiSiC components can have burls (or buds extending out) that are flat at the top and have angled sidewalls with defined slope. The thickness of these burls can be around 1 to 1.5 mm. Seeding with different sizes can be used. Seeding with 20-30 nm grain together with 10, 15 and 25 um spacing can be used to obtain high nucleation density, achieving uniform diamond coating across a 12 inch SiSiC wafer.

Example 2—After the deposition of a continuous diamond film, the diamond film can be etched using an aluminum mask. Islands of squares and circular structures, including but not limited to those formed as SiC/SiSiC burls or other substrates, can be defined. By adopting different seed mixtures, final thickness and grain size of diamond can be determined.

Example 3—Tools having structures generally configured as pyramids or cones with the tip radius of 200 nm to 2 um can be fabricated through reactive ion etching by using Al as the mask.

In the foregoing description, reference is made to the accompanying drawings that form a part thereof, and in which is shown by way of illustration specific exemplary embodiments in which the disclosure may be practiced. These embodiments are described in sufficient detail to enable those skilled in the art to practice the concepts disclosed herein, and it is to be understood that modifications to the various disclosed embodiments may be made, and other embodiments may be utilized, without departing from the scope of the present disclosure. The foregoing detailed description is, therefore, not to be taken in a limiting sense.

Reference throughout this specification to “one embodiment,” “an embodiment,” “one example,” or “an example” means that a particular feature, structure, or characteristic described in connection with the embodiment or example is included in at least one embodiment of the present disclosure. Thus, appearances of the phrases “in one embodiment,” “in an embodiment,” “one example,” or “an example” in various places throughout this specification are not necessarily all referring to the same embodiment or example. Furthermore, the particular features, structures, databases, or characteristics may be combined in any suitable combinations and/or sub-combinations in one or more embodiments or examples. In addition, it should be appreciated that the figures provided herewith are for explanation purposes to persons ordinarily skilled in the art and that the drawings are not necessarily drawn to scale.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims. It is also understood that other embodiments of this invention may be practiced in the absence of an element/step not specifically disclosed herein.

1. A tool, comprising:
a surface having at least one protrusion; and
a diamond coating formed from diamond grains sized so that 90% of the diamond grains are sized between 200 and 300 nanometers, with the diamond coating being deposited on the surface at a temperature below 500 degrees Celsius over the at least one protrusion.

2. The tool of claim 1, wherein the tool is a wafer handling tool that can include one or more of a wafer chuck, wafer holder, wafer stage, wafer tables, wafer substrate, die scanner, wafer table for chemical mechanical polishing (CMP), or wafer transporter.

3. The tool of claim 1, wherein the at least one protrusion is a burl.

4. The tool of claim 1, wherein the diamond coating on the surface is formed to have equally sized grains of less than 1 micron.

5. The tool of claim 1, wherein the diamond coating on the surface is formed to continuously cover the surface of the tool.

6. The tool of claim 1, wherein the diamond coating on the surface is formed to partially cover the tool.

7. The tool of claim 1, wherein the diamond coating on the surface is formed to partially cover burl protrusions on the tool.

8. The tool of claim 1, wherein the diamond coating thickness on the surface is between 200 nm to 100 microns.

9. The tool of claim 1, wherein the diamond coating thickness on the surface is uniformly thick over selected regions of the tool.

10. The tool of claim 1, wherein the diamond coating thickness on the surface is conformal over regions of the tool.

11. A method for diamond coating a tool, comprising
providing a tool having a surface with at least one protrusion; and
forming a diamond coating on the surface over the at least one protrusion, with the diamond coating being formed from diamond grains sized so that 90% of the grains are between 200 and 300 nanometers, and with the diamond coating being deposited on the surface at a temperature below 600 degrees Celsius over the at least one protrusion.

12. The method for diamond coating the tool of claim 11, wherein the tool is a wafer handling tool that can include one or more of a wafer chuck, wafer holder, wafer stage, wafer tables, wafer substrate, die scanner, wafer table for chemical mechanical polishing (CMP), or wafer transporter.

13. The method for diamond coating the tool of claim 11, wherein the at least one protrusion is a burl.

14. The method for diamond coating the tool of claim 11, wherein the diamond coating on the surface is formed to have equally sized grains of less than 1 micron.

15. The method for diamond coating the tool of claim 11, wherein the diamond coating on the surface is formed to continuously cover the tool.

16. The method for diamond coating the tool of claim 11, wherein the diamond coating on the surface is formed to partially cover the tool.

17. The method for diamond coating the tool of claim 11, wherein the diamond coating on the surface is formed to partially cover burl protrusions on the tool.

18. The method for diamond coating the tool of claim 11, wherein the diamond coating thickness on the surface is between 200 nm to 100 microns.

19. The method for diamond coating the tool of claim 11, wherein the diamond coating thickness on the surface is uniformly thick over selected regions of the tool.

20. The method for diamond coating the tool of claim 11, wherein the diamond coating thickness on the surface is conformal over regions of the tool.
